(19) United States
(12) Patent Application Publication
(10) Pub. No.: US 2010/0053114 A1
(43) Pub. Date: Mar. 4, 2010

(54) TOUCH PANEL APPARATUS AND METHOD FOR MANUFACTURING THE SAME

(76) Inventor: Hiroyuki Kaigawa, Mie (JP)

Correspondence Address: NIXON & VANDERHYE, PC, 901 NORTH GLEBE ROAD, 11TH FLOOR, ARLINGTON, VA, 22203, US

(21) Appl. No.: 12/447,760

(22) PCT Filed: Oct. 31, 2007
(86) PCT No.: PCT/JP2007/071219

§ 371 Date: Apr. 29, 2009

(30) Foreign Application Priority Data
Feb. 8, 2007 (JP) 2007-028812

(51) Int. Cl. G06F 3/041; G03F 7/00

(52) U.S. Cl. 345/174; 430/312

(57) ABSTRACT

A touch panel apparatus includes a position detection electrode formed in a touch region and made of ITO, and a wiring portion provided in a frame region and electrically connected to the position detection electrode. The wiring portion has a first pattern film extended from the position detection electrode and made of ITO, a second pattern film laminated on the first pattern film and made of IZO, and a third pattern film laminated on the second pattern film and made of silver or a silver alloy.

### TECHNICAL FIELD

The present invention relates to a touch panel apparatus and a manufacturing method thereof.

### BACKGROUND ART

Touch panel apparatuses for detecting a contact position have been widely used in recent years (see, e.g., Patent Document 1). The touch panel apparatuses are often mounted on top of display devices such as liquid crystal display panels.

The touch panel apparatuses are classified into a resistance film type, an electrostatic capacitance type (e.g., Patent Document 1), an infrared type, an ultrasonic type, an electromagnetic induction type, and the like, according to their operation principles. Among others, electrostatic capacitance type touch panel apparatuses are known to be preferably used for display devices because they are relatively less likely to degrade optical characteristics of the display devices.

An electrostatic capacitance type touch panel apparatus generally has a transparent electrode for position detection provided in a touch region, a plurality of electrode terminals provided in a peripheral region of the transparent electrode, and a current detection circuit for detecting a current flowing in the electrode terminals. The electrostatic capacitance type touch panel apparatus works as follows: when the touch region is touched, the transparent electrode is grounded at a touched position through electrostatic capacitance of an insulating material which is present between the transparent electrode and a human body. Since the resistance value between each electrode terminal and the grounded point varies depending on the position where a touch occurs, the touched position is detected by detecting a change in resistance value by the current detection circuit.

The touch panel apparatus has, for example, a rectangular touch region, and a frame region formed around the touch region. The electrode terminals and the current detection circuit are provided in the frame region, and extended wirings connecting the electrode terminals to the current detection circuit are formed in the frame region. The transparent electrode, the electrode terminals, and the extended wirings are usually formed by a printing method such as screen printing (see, e.g., Patent Document 2).

Patent Document 1: Japanese Published Patent Application No. 2003-66417

Patent Document 2: Japanese Translation of PCT International Application No. 2003-526853

### DISCLOSURE OF THE INVENTION

### Problems to be Solved by the Invention

Touch panel apparatuses have been required to reduce their overall size while assuring as large an area of the touch region as possible. It is therefore desirable to reduce the frame region as much as possible.

However, it is difficult to reduce the frame region of the touch panel apparatuses by the conventionally used printing method. More specifically, although the touch panel apparatuses can be relatively easily manufactured by the printing method, the printing method has problems, such as the need for a relatively large alignment margin, and print bleeding. Therefore, it is difficult to precisely form patterns of wirings, electrodes, and the like. As can been seen in, for example, mobile equipments, the size of display panels has been increasingly reduced and the frame of the display panels have been increasingly narrowed in recent years, and narrowing the frame of the touch panel apparatuses is therefore a very important issue.

The present invention was developed in view of the above-mentioned problems, and it is an object of the present invention to narrow the frame of a touch panel apparatus and to improve reliability of the touch panel apparatus.

### Means For Solving The Problems

In order to achieve the above object, a touch panel apparatus according to the present invention is a touch panel apparatus having a touch region which is a region where a position touched by a contact body is detected, and a frame region provided outside the touch region. The touch panel apparatus includes: a position detection electrode formed in the touch region and made of ITO; and a wiring portion provided in the frame region and electrically connected to the position detection electrode. The wiring portion has a first pattern film extended from the position detection electrode and made of ITO, a second pattern film laminated on the first pattern film and made of IZO, and a third pattern film laminated on the second pattern film and made of silver or a silver alloy.

A touch panel apparatus according to the present invention is a touch panel apparatus having a touch region which is a region where a position touched by a contact body is detected, and a frame region provided outside the touch region. The touch panel apparatus includes: a position detection electrode formed in the touch region and made of ITO; and a wiring portion provided in the frame region and electrically connected to the position detection electrode. The wiring portion has a first pattern film extended from the position detection electrode and made of ITO, a second pattern film laminated on the first pattern film and made of IZO, and a third pattern film laminated on the second pattern film and made of aluminum or an aluminum alloy.

Preferably, the wiring portion is formed by photolithography.

A method for manufacturing a touch panel apparatus according to the present invention is a method for manufacturing a touch panel apparatus including a position detection electrode and a wiring portion. The position detection electrode is formed in a touch region which is a region where a position touched by a contact body is detected, and the wiring portion is provided in a frame region located outside the touch region, and is electrically connected to the position detection electrode. The wiring portion has a first pattern film extended from the position detection electrode and made of ITO, a second pattern film laminated on the first pattern film and made of IZO, and a third pattern film laminated on the second pattern film and made of silver or a silver alloy. The method includes the steps of: sequentially laminating an ITO layer, an IZO layer, and a silver or silver alloy layer in this order; patterning the silver or silver alloy layer and the IZO layer by photolithography to form the third pattern film and the second pattern film; and patterning the ITO layer by photolithography to form the first pattern film.

A method for manufacturing a touch panel apparatus according to the present invention is a method for manufacturing a touch panel apparatus including a position detection electrode and a wiring portion. The position detection electrode is formed in a touch region which is a region where a position touched by a contact body is detected, and the wiring portion is provided in a frame region located outside the touch region, and is electrically connected to the position detection electrode. The wiring portion has a first pattern film extended from the position detection electrode and made of ITO, a second pattern film laminated on the first pattern film and made of IZO, and a third pattern film laminated on the second pattern film and made of aluminum or an aluminum alloy. The method includes the steps of: sequentially laminating an ITO layer, an IZO layer, and a silver or silver alloy layer in this order; patterning the silver or silver alloy layer and the IZO layer by photolithography to form the third pattern film and the second pattern film; and patterning the ITO layer by photolithography to form the first pattern film.

Functions of the present invention will now be described.

The touch panel device described above detects a touched position when the contact body touches the touch region. More specifically, electrostatic capacitance is formed between the contact body touching the touch region and the position detection electrode. The position touched by the contact body is detected by detecting the electrostatic capacitance through the wiring portion.

In the present invention, the wiring portion is formed by a lamination of the first through third pattern films, and the third pattern film is made of silver or a silver alloy having a low electrical resistance. Therefore, electrostatic capacitance generated in the touch region can be accurately transmitted by the wiring portion. According to another invention, the third pattern film is made of aluminum or an aluminum alloy. In this case as well, electrostatic capacitance generated in the touch region can be accurately transmitted by the wiring portion.

In manufacturing of the touch panel apparatus described above, the wiring portion can be formed by photolithography. More specifically, in the case where the third pattern film is made of silver or a silver alloy, the ITO layer, the IZO layer, the silver or silver alloy layer are first sequentially laminated in this order on a transparent substrate. The silver or silver alloy layer and the IZO layer are then patterned by photolithography to form the third pattern film and the second pattern film. Thereafter, the ITO layer is patterned by photolithography to form the first pattern film.

In this case, since the second pattern film made of IZO is interposed between the third pattern film made of silver or a silver alloy and the first pattern film made of ITO, no electrolytic corrosion occurs between the first pattern film (ITO) and the third pattern film (silver or a silver alloy). Since electrolytic corrosion is prevented from occurring during etching in photolithography, the wiring portion is formed accurately and reliably, and reliability of the wiring portion is improved.

Moreover, since the wiring portion can be formed by photolithography instead of a printing method, problems such as a large alignment margin and print bleeding do not occur, and the wiring portion can be formed precisely. As a result, the frame of the touch panel apparatus can be narrowed.

Even when the third pattern film is made of aluminum or an aluminum alloy, the frame of the touch panel apparatus can be narrowed, and reliability of the touch panel apparatus can be improved, as in the case the third pattern film is made of silver or a silver alloy.

### EFFECTS OF THE INVENTION

According to the present invention, since the wiring portion has the first pattern film made of ITO, the second pattern film laminated on the first pattern film and made of IZO, and the third pattern film laminated on the second pattern film and made of silver or a silver alloy, the frame region of the touch panel apparatus can be narrowed, and reliability of the touch panel apparatus can be improved.

### BRIEF DESCRIPTION OF THE DRAWINGS

FIG. 1 is a plan view showing an external appearance of a touch panel apparatus 1.

FIG. 2 is a cross-sectional view taken along line II-II in FIG. 1.

FIG. 3 is an enlarged cross-sectional view showing a structure of a wiring portion.

FIG. 4 is a cross-sectional view showing an ITO layer, an IZO layer, and a silver or silver alloy layer which are laminated on a glass substrate.

FIG. 5 is a plan view showing a photoresist for patterning the silver or silver alloy layer and the IZO layer.

FIG. 6 is a cross-sectional view showing the photoresist for patterning the silver or silver alloy layer and the IZO layer.

FIG. 7 is a plan view showing a state in which second and third pattern films and second and third conductive portions have been formed.

FIG. 8 is a cross-sectional view showing the formed second and third pattern films.

FIG. 9 is a plan view showing a photoresist for patterning the ITO layer.

FIG. 10 is a cross-sectional view showing the photoresist for patterning the ITO layer.

FIG. 11 is a plan view showing formed wiring portions and a formed frame conductive portion

FIG. 12 is a cross-sectional view showing a formed wiring portion.

FIG. 13 is a cross-sectional view showing an insulating film having a contact hole formed therein.

### DESCRIPTION OF THE REFERENCE NUMERALS

A touch region
B frame region
1 touch panel apparatus
10 wiring portion
11 frame conductive portion
13 mount region
16 glass substrate
17 transparent conductive film
17a position detection electrode
17b first conductive portion
17c first pattern film
18 insulating film
22 second pattern film
23 third pattern film
25 terminal
26 contact hole
32 second conductive portion
33 third conductive portion
41 ITO layer
42 IZO layer
43 silver alloy layer
45, 46 photoresist

### BEST MODE FOR CARRYING OUT THE INVENTION

Hereinafter, embodiments of the present invention will be described in detail with reference to the accompanying drawings. Note that the present invention is not limited to the following embodiments.

### First Embodiment

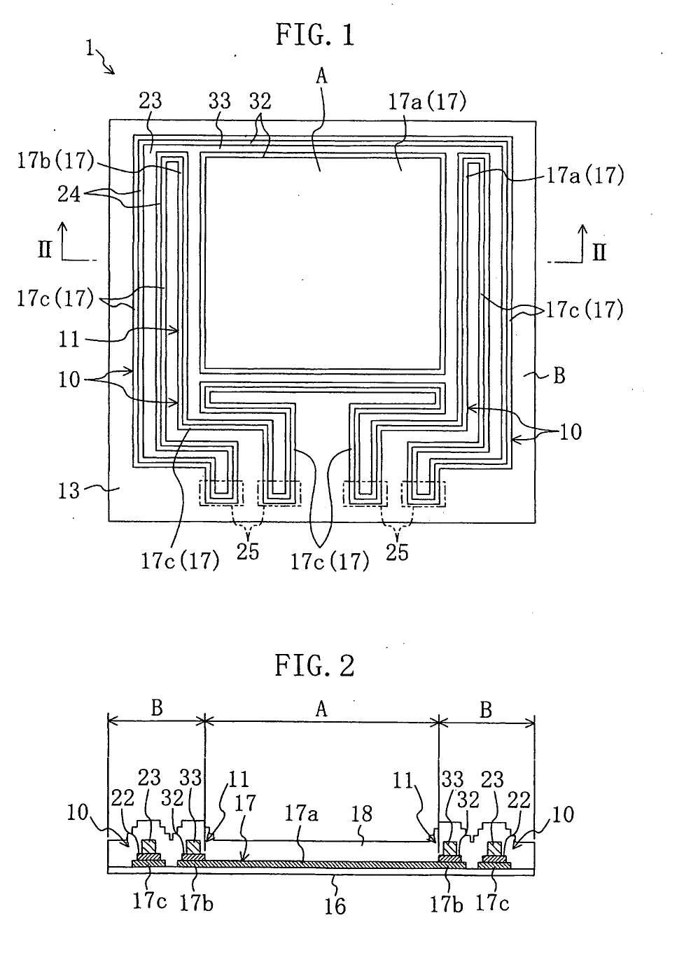

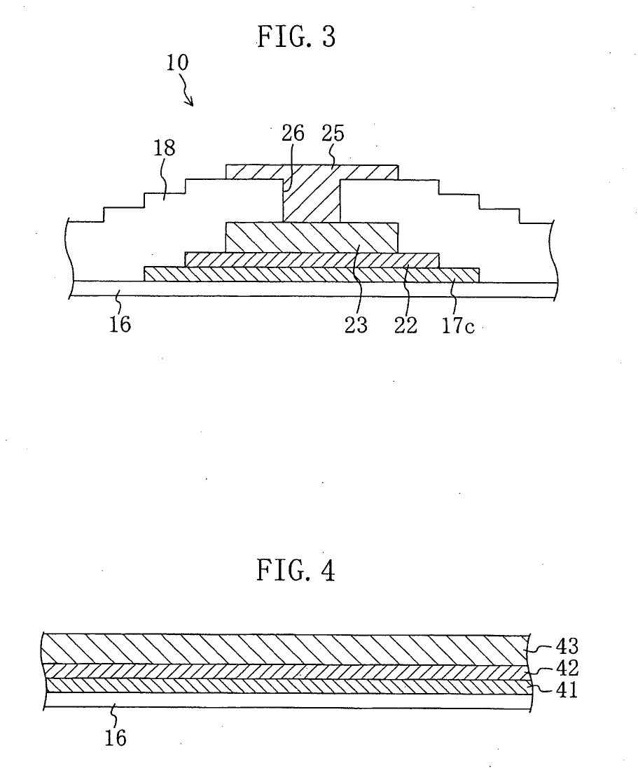

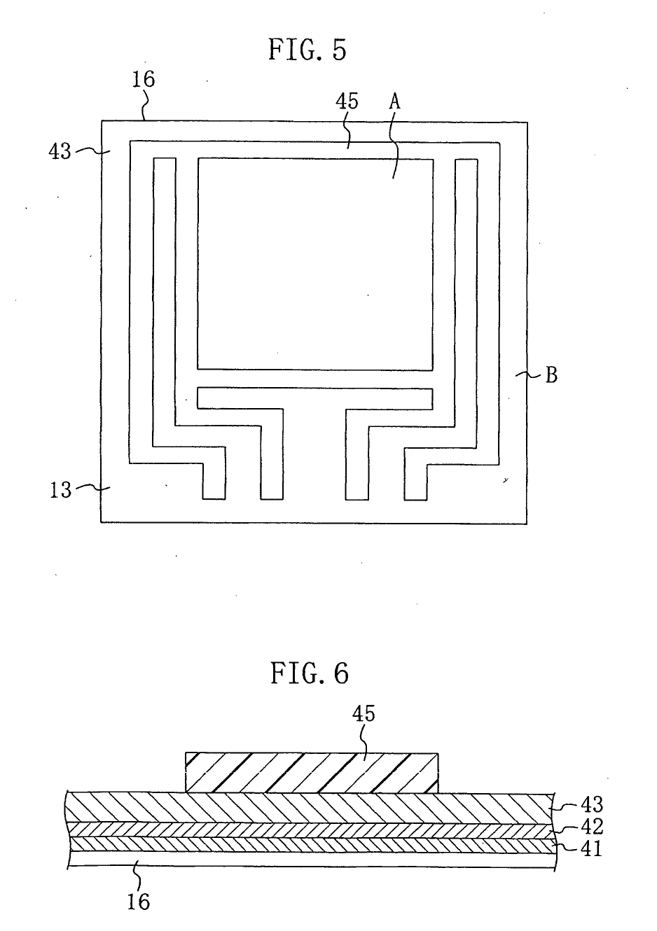

FIGS. 1 through 13 show a first embodiment of the present invention. FIG. 1 is a plan view showing an external appearance of a touch panel apparatus 1. FIG. 2 is a cross-sectional view taken along line II-II in FIG. 1. FIG. 3 is an enlarged cross-sectional view showing a structure of a wiring portion 10. FIGS. 4, 6, 8, 10, 12, and 13 are cross-sectional views illustrating a manufacturing process of the touch panel apparatus 1. FIGS. 5, 7, 9, and 11 are plan views illustrating the manufacturing process of the touch panel apparatus 1.

The touch panel apparatus 1 is an electrostatic capacitance type touch panel apparatus, and is placed on the user side of a display device such as a liquid crystal display panel (not shown).

More specifically, as shown in FIGS. 1 and 2, the touch panel apparatus 1 has a glass substrate 16 which is a rectangular plate-shaped transparent substrate, and a transparent conductive film 17 patterned on a surface of the glass substrate 16. On the glass substrate 16, the touch panel apparatus 1 has a touch region A which is a region where a position touched by a contact body (e.g., a stylus, a fingertip or the like) is detected, and a frame region B provided outside the touch region A. The “transparent substrate” herein means a substrate which allows visible light to transmit therethrough, and includes a colorless transparent substrate and a colored transparent substrate.

The touch region A is formed in a rectangular region, and is positioned in the middle in the horizontal direction and in the upper side in FIG. 1. Accordingly, a mount region 13 where, for example, an FPC (flexible printed circuit) serving as a detection circuit for receiving and outputting a positional detection signal is mounted, is formed in the frame region on the lower side in FIG. 1. No touched position is detected in the frame region B even if the frame region B is touched by the contact body.

The transparent conductive film 17 is made of, for example, ITO (Indium Tin Oxide). The transparent conductive film 17 has a thickness of, for example, about 5 to 25 nm. The transparent conductive film 17 is formed by a rectangular position detection electrode 17a formed over the whole touch region, a rectangular frame-shaped first conductive portion 17b formed continuously in the outer periphery of the rectangular position detection electrode 17a, and four first pattern films 17c extended from the position detection electrode 17a through the first conductive portion 17b. In other words, the position detection electrode 17a, the first conductive portion 17b, and the first pattern films 17c are formed as a single continuous ITO film as a whole. The first conductive portion 17b and the first pattern films 17c are formed in the frame region B.

The touch panel apparatus 1 further has a frame conductive portion 11 and four wiring portions 10, both in the frame region B.

The frame conductive portion 11 is formed in a rectangular frame shape along the outer periphery of the touch region A, and is formed by the first conductive portion 17b, a second conductive portion 32 laminated on the first conductive portion 17b, and a third conductive portion 33 laminated on the second conductive portion 32. The second and third conductive portions 32, 33 are formed in a rectangular frame shape so as to overlap the rectangular frame-shaped first conductive portion 17b. As shown in FIG. 2, the first through third conductive portions 17b, 32, 33 are formed in a stepped shape so that the width decreases upward. The frame conductive portion 11 as a whole is therefore electrically connected to the position detection electrode 17a.

The wiring portions 10 are electrically connected to the position detection electrode 17a through the frame conductive portion 11. As shown in FIG. 2, one end of each wiring portion 10 is electrically connected to a corresponding corner of the frame conductive portion 11, while the other end of each wiring portion 10 is extended to the mount region 13, and a terminal 25 is formed at that end of each wiring portion 10.

As shown in FIGS. 2 and 3, each wiring portion 10 is formed as a wiring pattern of a three-layer structure in which the first pattern film 17c, a second pattern film 22, and a third pattern film 23 are laminated in this order. The wiring portions 10 are formed by photolithography, as described later.

More specifically, the first pattern film 17c is made of an ITO film as described above, and the second pattern film 22 made of an IZO (Indium Zinc Oxide) film is laminated on the surface of the first pattern film 17c. The second pattern film 22 has a sheet resistance of about 300Ω/□ to 1 kΩ/□ when the thickness is 10 nm. The third pattern film 23 made of silver or a silver alloy is laminated on the surface of the second pattern film 22.

The second pattern film 22 has a thickness of, for example, about 10 to 30 nm, and the third pattern film 23 has a thickness of, for example, about 100 to 300 nm. As shown in FIG. 3, the first through third pattern films 17a, 22, 23 are formed in a stepped shape so that the width decreases upward.

The wiring portions 10, the frame conductive portion 11, and the position detection electrode 17a are covered by a transparent insulating film 18 as a protective layer. The insulating film 18 has a thickness of, for example, about 50 to 700 nm. A contact hole 26 is formed in the insulating film 18 at a position above the end of each wiring portion 10 in the mount region 13. Each terminal 25 formed on the insulating film 18 is connected to the third pattern film 23 of a corresponding one of the wiring portions 10 through a corresponding one of the contact holes 26. The terminals 25 are arranged in line in the horizontal direction in FIG. 1. The FPC is connected to the terminals 25.

When the contact body such as a stylus touches the surface of the insulating film 18, electrostatic capacitance formed between the contact body and a part of the opposing position detection electrode 17a is detected by a detection circuit such as the FPC. The position touched by the contact body is detected in this manner.

[Manufacturing Method]

Hereinafter, a manufacturing method of the touch panel apparatus 1 will be described.

First, as shown in FIG. 4, an ITO layer 41, an IZO layer 42, and a silver or silver alloy layer 43 are sequentially laminated in this order on the surface of the glass substrate 16. The ITO layer 41, the IZO layer 42, and the silver or silver alloy layer 43 can be formed by sputtering. The thickness of the ITO layer 41 is, for example, about 5 to 25 nm, the thickness of the IZO layer 42 is, for example, about 10 to 30 nm, and the thickness of the silver or silver alloy layer 43 is, for example, about 100 to 300 nm.

The silver or silver alloy layer 43 and the IZO layer 42 are then patterned by photolithography to form the third pattern films 23 and the second pattern films 22.

More specifically, as shown in FIGS. 5 and 6, a photoresist 45 is formed on the surface of the silver or silver alloy layer 43. The photoresist 45 is patterned so as to cover a region which will later become the second and third conductive portions 32, 33 of the frame conductive portion 11 and a region which will later become the second and third pattern films 22, 23 of the wiring portions 10.

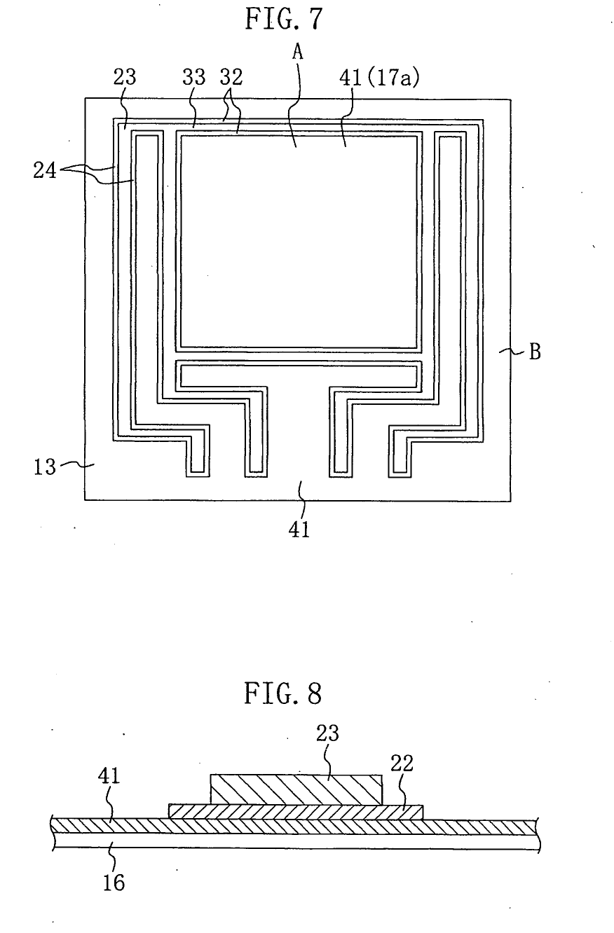

As shown in FIGS. 7 and 8, the silver or silver alloy layer 43 and the IZO layer 42 which have not been covered by the photoresist 45 are removed by etching to expose the ITO layer 41. The photoresist 45 is then removed, whereby the second and third pattern films 22, 23 and the second and third conductive portions 32, 33 are formed. At this time, the position detection electrode 17a is formed by the ITO layer 41 exposed in the touch region A.

The ITO layer 41 is then patterned by photolithography to form the first pattern films 17c.

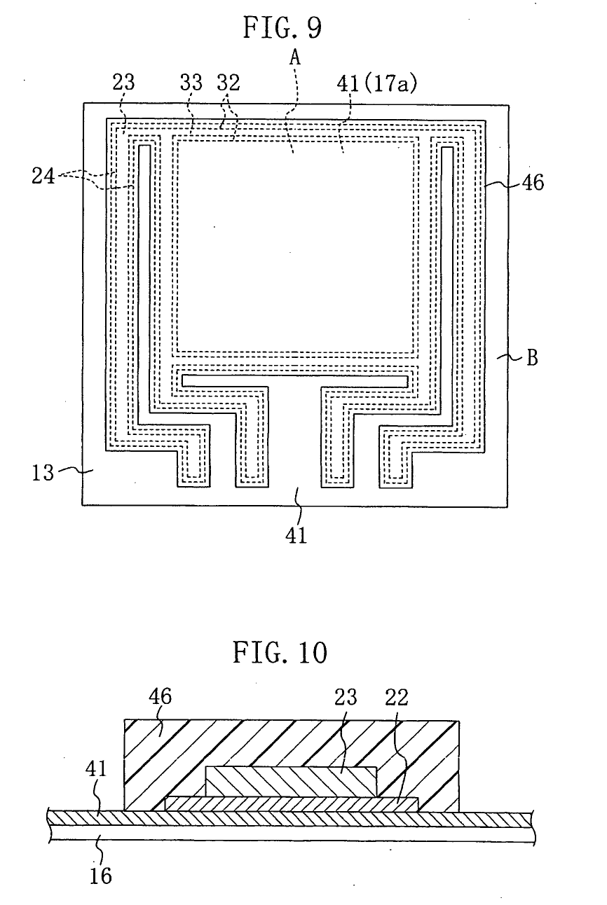

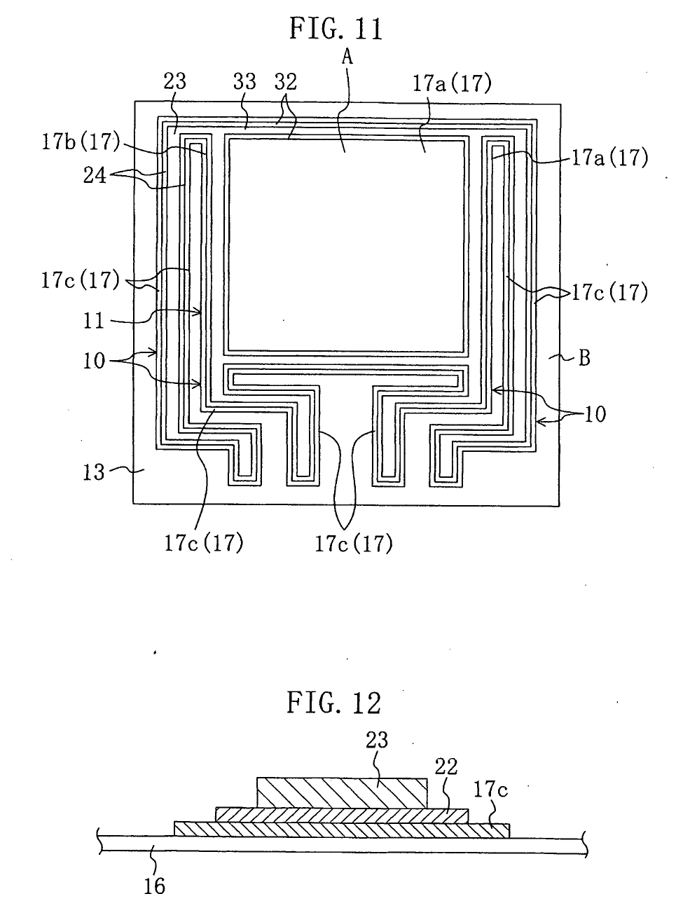

More specifically, as shown in FIGS. 9 and 10, a photoresist 46 is patterned so as to cover the touch region A, a region which will later become the frame conductive portion 11, and a region which will later become the wiring portions 10. As shown in FIGS. 11 and 12, the ITO layer 41 which has not been covered by the photoresist 46 is removed by etching to expose the glass substrate 16. The photoresist 46 is then removed, whereby the first pattern films 17c and the first conductive portion 17b are formed. The wiring portions 10 and the frame conductive portion 11 are formed in this manner.

A transparent insulating film 18 is then deposited over the glass substrate 16 so as to cover the position detection electrode 17a, the wiring portions 10, and the frame conductive portion 11. The thickness of the insulating film 18 is, for example, about 50 to 700 nm.

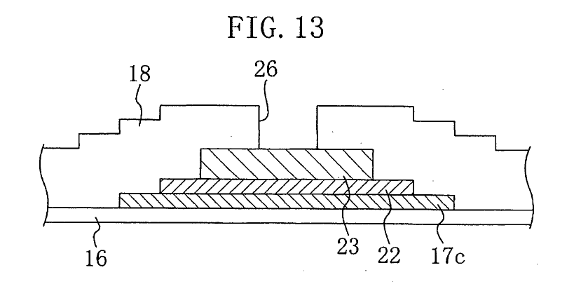

Thereafter, the terminals 25 are formed. More specifically, as shown in FIG. 13, a contact hole 26 is formed above the end of each wiring portion 10 in the mount region 13. Thus, the third pattern film 23 is exposed at the end of each wiring portion 10. An IZO layer (not shown) is then deposited on the surface of the insulating film 18 and inside each contact hole 26. Then, the IZO layer deposited is patterned by photolithography to form the terminals 25 as shown in FIGS. 1 and 3. An FPC is then mounted to each terminal 25. The touch panel apparatus 1 is manufactured in this manner.

### Effects of the First Embodiment

As described above, according to the first embodiment, each wiring portion 10 is formed by the first pattern film 17c made of ITO, the second pattern film 22 laminated on the first pattern film 17c and made of IZO, and the third pattern film 23 laminated on the second pattern film 22 and made of silver or a silver alloy. Accordingly, the frame region of the touch panel apparatus 1 can be narrowed, and reliability of the touch panel apparatus 1 can be improved.

In other words, since the third pattern film 23 is made of silver or a silver alloy having a low electrical resistance, electrostatic capacitance generated in the touch region A can be accurately transmitted by the wiring portions 10.

Moreover, since the wiring portions 10 can be formed by photolithography instead of a printing method, problems such as a large alignment margin and print bleeding do not occur, and the wiring portions 10 can be formed precisely. As a result, the frame of the touch panel apparatus 1 can be narrowed. In other words, the area of the frame region B can be reduced while maintaining a relatively large area of the touch region A.

In addition, since the second pattern film made of IZO is interposed between the third pattern film made of silver or a silver alloy and the first pattern film made of ITO, electrolytic corrosion can be prevented from occurring between the first pattern film (ITO) and the third pattern film (silver or a silver alloy) during formation of the wiring portions 10 by photolithography. In other words, electrolytic corrosion can be prevented from occurring during etching in photolithography. Therefore, the wiring portions 10 can be reliably and precisely formed, and reliability of the wiring portions 10 can be improved.

### Other Embodiments

The first embodiment was described with respect to the case where the respective third pattern films 23 of the wiring portions 10 and the third conductive portion 33 of the frame conductive portion II are made of silver or a silver alloy. However, the present invention is not limited to this, and the third pattern films 23 and the third conductive portion 33 may be made of aluminum or an aluminum alloy (e.g., AlNb).

In this case as well, electrolytic corrosion between the first pattern film 17c made of ITO and the third pattern film 23 made of aluminum or an aluminum alloy can be prevented. In other words, since the wiring portions 10 can be formed by photolithography, the frame of the touch panel apparatus 1 can be narrowed, and reliability of the touch panel apparatus 1 can be improved, as described in the first embodiment.

The first embodiment was described with respect to an example in which the transparent conductive film 17 made of ITO is formed on the surface of the glass substrate 16. However, the present invention is not limited to this. An insulating layer such as SiO₂ may be uniformly formed on the surface of the glass substrate 16, and the transparent conductive film 17 may be formed on the surface of the insulating layer. This insulating layer is preferably formed with a thickness of, for example, about several tens of nanometers. This enables the transparent conductive film 17 to be improved in adhesion property to the glass substrate 16.

### INDUSTRIAL APPLICABILITY

As has been described above, the present invention is useful for a touch panel apparatus and a manufacturing method thereof, and is suitable especially for narrowing the frame of the touch panel apparatus and for improving reliability of the touch panel apparatus.

1. A touch panel apparatus having a touch region which is a region where a position touched by a contact body is detected, and a frame region provided outside the touch region, comprising:
a position detection electrode formed in the touch region and made of ITO; and
a wiring portion provided in the frame region and electrically connected to the position detection electrode, wherein
the wiring portion has a first pattern film extended from the position detection electrode and made of ITO, a second pattern film laminated on the first pattern film and made of IZO, and a third pattern film laminated on the second pattern film and made of silver or a silver alloy.

2. A touch panel apparatus having a touch region which is a region where a position touched by a contact body is detected, and a frame region provided outside the touch region, comprising:
a position detection electrode formed in the touch region and made of ITO; and
a wiring portion provided in the frame region and electrically connected to the position detection electrode, wherein
the wiring portion has a first pattern film extended from the position detection electrode and made of ITO, a second pattern film laminated on the first pattern film and made of IZO, and a third pattern film laminated on the second pattern film and made of aluminum or an aluminum alloy.

3. The touch panel apparatus of claim 1, wherein the wiring portion is formed by photolithography.

4. A method for manufacturing a touch panel apparatus including a position detection electrode and a wiring portion, wherein
the position detection electrode is formed in a touch region which is a region where a position touched by a contact body is detected, and the wiring portion is provided in a frame region located outside the touch region, and is electrically connected to the position detection electrode, and
the wiring portion has a first pattern film extended from the position detection electrode and made of ITO, a second pattern film laminated on the first pattern film and made of IZO, and a third pattern film laminated on the second pattern film and made of silver or a silver alloy, the method comprising the steps of:
sequentially laminating an ITO layer, an IZO layer, and a silver or silver alloy layer in this order;
patterning the silver or silver alloy layer and the IZO layer by photolithography to form the third pattern film and the second pattern film; and
patterning the ITO layer by photolithography to form the first pattern film.

5. A method for manufacturing a touch panel apparatus including a position detection electrode and a wiring portion, wherein
the position detection electrode is formed in a touch region which is a region where a position touched by a contact body is detected, and the wiring portion is provided in a frame region located outside the touch region, and is electrically connected to the position detection electrode, and
the wiring portion has a first pattern film extended from the position detection electrode and made of ITO, a second pattern film laminated on the first pattern film and made of IZO, and a third pattern film laminated on the second pattern film and made of aluminum or an aluminum alloy, the method comprising the steps of:
sequentially laminating an ITO layer, an IZO layer, and an aluminum or aluminum alloy layer in this order;
patterning the aluminum or aluminum alloy layer and the IZO layer by photolithography to form the third pattern film and the second pattern film; and
patterning the ITO layer by photolithography to form the first pattern film.
